(19) United States
(12) Patent Application Publication
(10) Pub. No.: US 2009/0058486 A1
(43) Pub. Date: Mar. 5, 2009

(54) MASTER-SLAVE CIRCUIT AND CONTROL METHOD OF THE SAME

(75) Inventors: Tadashi OZAWA, Kasugai (JP); Masaki Komaki, Kasugai (JP); Katsuhito Hashiba, Kasugai (JP); Tatsuki Sahashi, Kasugai (JP); Yukihiro Sakata, Kasugai (JP); Hiroto Nishihata, Kasugai (JP); Akihiro Miki, Kasugai (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kawasaki-shi (JP)

(21) Appl. No.: 12/193,261

(22) Filed: Aug. 18, 2008

(30) Foreign Application Priority Data
Sep. 4, 2007 (JP) 2007-228556

(51) Int. Cl. H03K 3/289

(52) U.S. Cl. 327/203

(57) ABSTRACT

A master-slave circuit that includes a master circuit having input data stored therein, a storage unit for receiving the input data in response to receiving a sleep mode setting signal that sets a sleep mode, and for storing the input data, and a first control unit for interrupting the supply of a power supply voltage to the master circuit after the input data is stored in the storage unit.

### CROSS-REFERENCE TO RELATED APPLICATIONS

This application claims the benefit of priority from Japanese Patent Application No. 2007-228556 filed on Sep. 4, 2007, the entire contents of which are incorporated herein by reference.

### BACKGROUND OF THE INVENTION

1. Field of the Invention

The application relates to a master-slave circuit and a method of controlling the master-slave circuit.

2. Description of the Related Art

In a D flip-flop circuit, when a power supply voltage is interrupted to achieve low power consumption in order to save power, this power supply voltage interruption causes an inverter in a D flip-flop circuit to become inoperative, causing the data latched in the D flip-flop circuit to be deleted. Therefore, the problem with the D flip-flop circuit is that the latched data has been deleted when the D flip-flop recovers to a non-power-saving state from a power-saving state.

Japanese Patent Laid-Open Publication No. 1996-191234 discloses a D flip-flop circuit having the following capability. When the D flip-flop circuit becomes inoperative by turning off the power supply, the D flip-flop circuit stores an internal state before turning off the power supply, and then, when the D flip-flop circuit becomes operative by turning on the power supply, the D flip-flop circuit restores the internal state before turning off the power supply.

The D flip-flop circuit includes a memory circuit equipped with a positive terminal and a negative terminal. In addition, another power supply that is different from a power supply used for master and slave units supplies power to the memory circuit.

The D flip-flop circuit disconnects a path between the negative terminal in the memory circuit and an input terminal in the master unit and a path between the positive terminal in the memory circuit and the input terminal in the slave unit when the D flip-flop circuit is in a power-saving state. The D flip-flop circuit, on the other hand, disconnects the path between the negative terminal in the memory circuit and the input terminal in the master unit when the master unit and the slave unit are disconnected.

In a typical master-slave circuit such as the D flip-flop circuit, it is advantageous to interrupt a power supply to a deactivated circuit to achieve low power consumption. However, the master-slave circuit is generally used for storing data. Consequently, when the power supply to the master-slave circuit is interrupted, a voltage that is needed to store data is not supplied to the D flip-flop circuit. For the above reason, it is difficult for the master-slave circuit to satisfy both the low power consumption and data storing capability.

### SUMMARY OF THE INVENTION

According to one aspect of an embodiment, a master-slave circuit is provided that includes a master circuit having input data stored therein, a storage unit for receiving the input data in response to receiving a sleep mode setting signal that sets a sleep mode, and for storing the input data, and a first control unit for interrupting the supply of a power supply voltage to the master circuit after the input data is stored in the storage unit.

Additional advantages and novel features of the invention will be set forth in part in the description that follows, and in part will become more apparent to those skilled in the art upon examination of the following or upon learning by practice of the invention.

### BRIEF DESCRIPTION OF THE DRAWINGS

FIG. 1 shows a circuit diagram of a flip-flop circuit in accordance with a first embodiment;

FIG. 2 shows a detailed circuit diagram of the flip-flop circuit in accordance with the first embodiment;

FIG. 3 shows a circuit diagram of a delay control circuit in accordance with the first embodiment;

FIG. 4 shows a timing chart of the flip-flop circuit in a normal mode in accordance with the first embodiment;

FIG. 5 shows a timing chart of the flip-flop circuit in a sleep mode in accordance with the first embodiment;

FIG. 6 shows a circuit diagram of a flip-flop circuit in accordance with a second embodiment;

FIG. 7 shows a detailed circuit diagram of a part of the flip-flop circuit in accordance with the second embodiment;

FIG. 8 shows a circuit diagram of a flip-flop circuit in accordance with a third embodiment;

FIG. 9 shows a block diagram of a flip-flop circuit in accordance with a fourth embodiment;

FIG. 10 shows a detailed circuit diagram of a part of the flip-flop circuit in accordance with the fourth embodiment;

FIG. 11 shows a circuit diagram of a slave-side clock generation circuit in accordance with the fourth embodiment;

FIG. 12 shows a circuit diagram of a scan-side clock generation circuit in accordance with the fourth embodiment;

FIG. 13 shows a circuit diagram of a master circuit-slave circuit supply voltage control circuit in accordance with the fourth embodiment;

FIG. 14 shows a timing chart of the flip-flop circuit when the flip-flop circuit shifts to a sleep mode from a normal mode in accordance with the fourth embodiment;

FIG. 15 shows a timing chart of the flip-flop circuit when the flip-flip circuit shifts to the normal mode from the sleep mode in accordance with the fourth embodiment;

FIG. 16 shows a circuit diagram of a flip-flop circuit in accordance with a fifth embodiment;

FIG. 17 shows a circuit diagram of a flip-flop circuit in accordance with a sixth embodiment; and

FIG. 18 shows a circuit diagram of a flip-flop circuit in accordance with a seventh embodiment invention.

### DETAILED DESCRIPTION

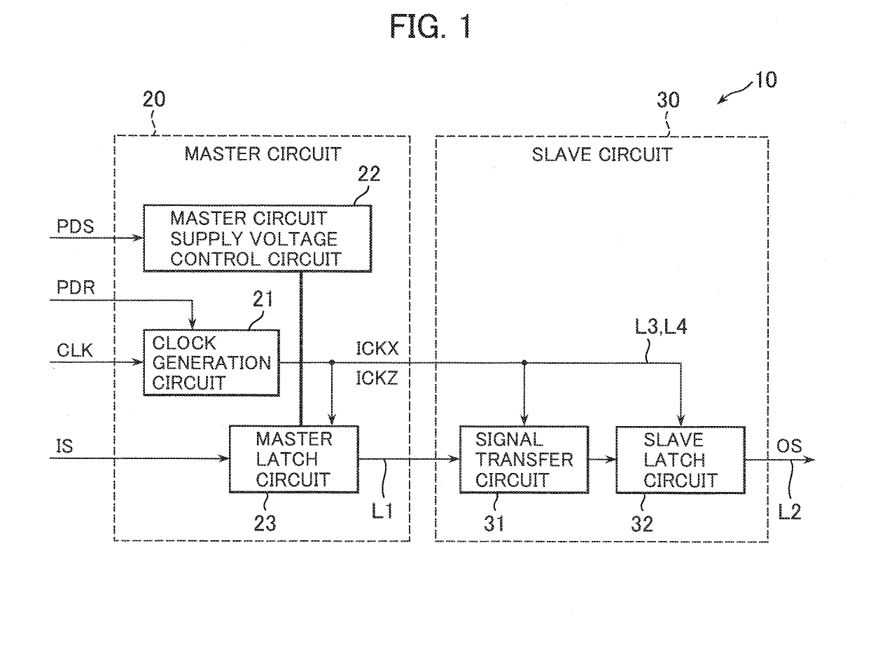

A first embodiment will be described with reference to FIGS. 1 through 5. A master-slave circuit will be described with reference to a flip-flop circuit 10. FIG. 1 shows a circuit diagram of the flip-flop circuit 10. The flip-flop circuit 10 includes a master circuit 20 and a slave circuit 30. The master circuit 20 further includes a clock generation circuit 21, a master circuit supply voltage control circuit 22 and a master latch circuit 23. The slave circuit 30 includes a signal transfer circuit 31 and a slave latch circuit 32.

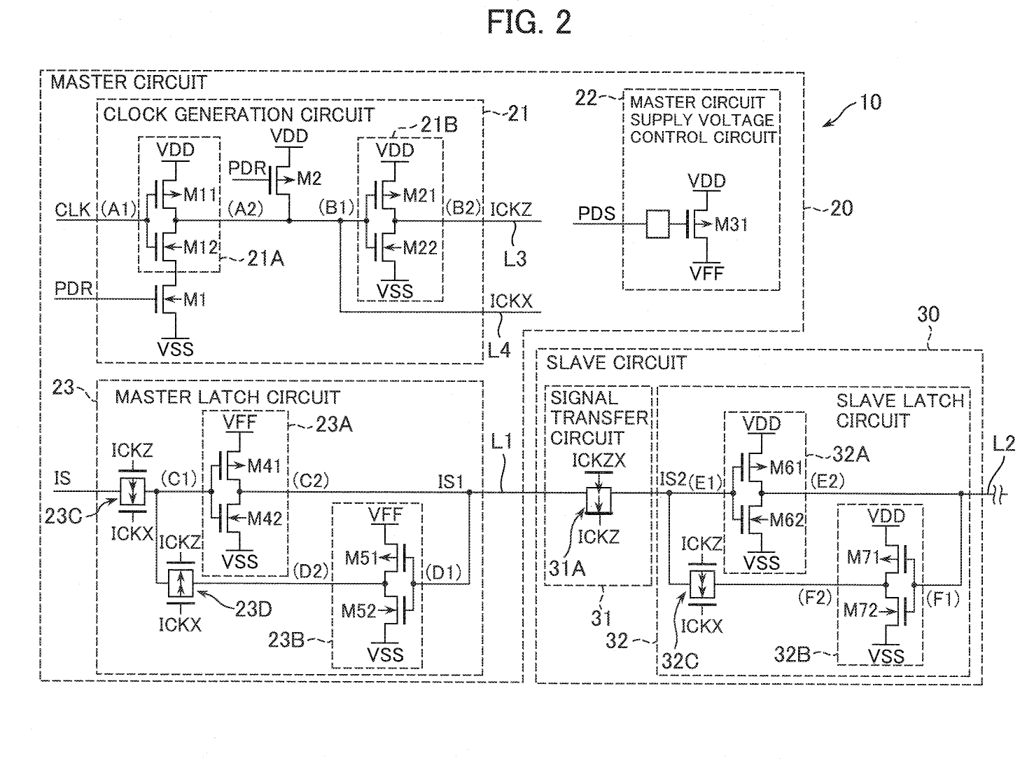

As shown in FIG. 2, the clock generation circuit 21 includes an inverter 21A, an inverter 21B, an n-channel transistor M1, and a p-channel transistor M2. A VDD shown in FIG. 2 is a power supply line.

The inverter 21A includes a p-channel transistor M11 and an n-channel transistor M12. A source of the n-channel transistor M12 is coupled to a drain of the n-channel transistor M1. A ground potential VSS is supplied to a source of the n-channel transistor M1. An output A2 of the inverter 21A is coupled to an input B1 of the inverter 21B. A reference symbol “A1” in FIG. 2 indicates an input of the inverter 21A and a reference symbol “B2” indicates an output of the inverter 21B.

A drain of the p-channel transistor M2 is coupled to the input B1 of the inverter 21B. The inverter 21B includes a p-channel transistor M21 and an n-channel transistor M22.

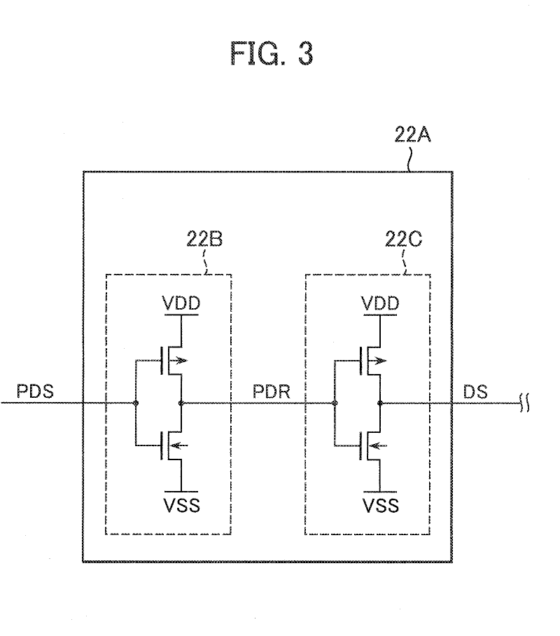

The master circuit supply voltage control circuit 22 includes a delay control circuit 22A and a p-channel transistor M31. An output of the delay control circuit 22A is coupled to a gate of the p-channel transistor M31. A power supply voltage is supplied to a source of the p-channel transistor M31 via the power supply line VDD. As shown in FIG. 3, in the first embodiment, the delay control circuit 22A includes an inverter 22B and an inverter 22C, which are coupled in a multi-stage manner.

Returning to FIG. 2, the master latch circuit 23 of FIG. 2 includes an inverter 23A, an inverter 23B, a transfer gate 23C and a transfer gate 23D. The transfer gate 23C is coupled to an input C1 of the inverter 23A. The inverter 23A includes a p-channel transistor M41 and an N type channel transistor M42.

An output C2 of the inverter 23A of FIG. 2 is coupled to an input D1 of the inverter 23B. The inverter 23B of FIG. 2 includes a p-channel transistor M51 and an n-channel transistor M52. An output D2 of the inverter 23 B is coupled to an input C1 of the inverter 23A via the transfer gate 23D.

As shown in FIG. 2, the signal transfer circuit 31 in the slave circuit 30 includes a transfer gate 31A.

The slave latch circuit 32 of FIG. 2 includes an inverter 32A, an inverter 32B, and a transfer gate 32C. An input E1 of the inverter 32A is coupled to the output C2 of the inverter 23A via the signal transfer circuit 31. The signal transfer circuit 31 is coupled to an output line L1. The inverter 32A includes a p-channel transistor M61 and an n-channel transistor M62. The output line L1 corresponds to an input data transfer path in the first embodiment.

An input E2 of the inverter 32A of FIG. 2 is coupled to an output line L2 and an input F1 of the inverter 32B of FIG. 2. The inverter 32B includes a p-channel transistor M71 and an n-channel transistor M72. An output F2 of the inverter 32B is coupled to the input E1 of the inverter 32A via the transfer gate 32C.

Next, operation of the flip-flop circuit 10 according to the first embodiment will be described. One of a normal mode and a sleep mode can be set to the flip-flop circuit 10. In the sleep mode, the flip-flop circuit 10 steps down a power supply voltage from a power supply voltage in the normal mode without receiving an external signal in order to reduce the power consumption.

As shown in FIG. 1, a clock signal CLK is input to the clock generation circuit 21 in the normal mode. As shown in FIG. 2, the clock signal CLK is input to each gate of the transistors M11 and M12 of the clock generation circuit 21 via the input A1 of the inverter 21A.

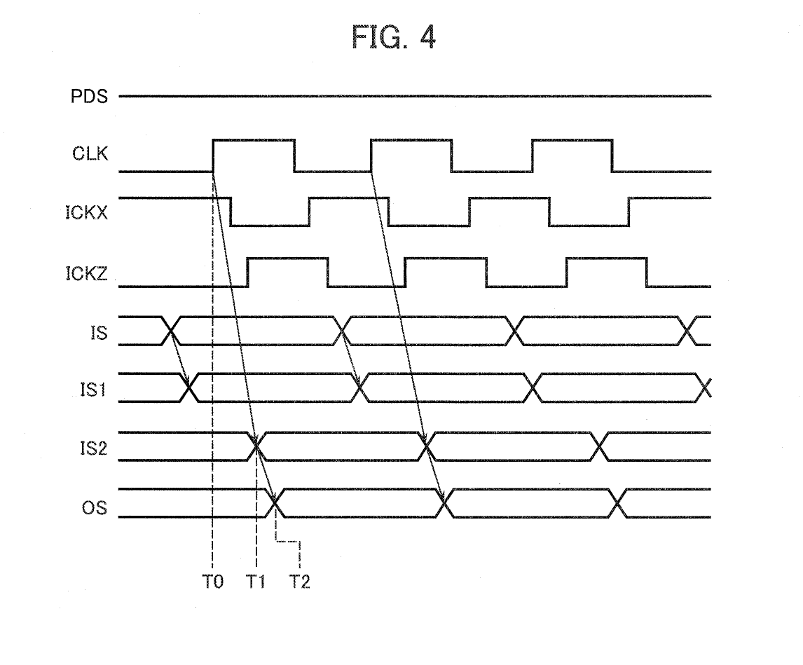

Supplying the clock signal CLK having a low level to each gate of the transistors M11 and 12 causes the p-channel transistor M11 to switch to an ‘ON’ state and causes the n-channel transistor M12 to switch to an ‘OFF’ state. Consequently, the level of an output from the inverter 21A shifts to a high level, so that the level of a control signal ICKX shifts to a high level in an interval until time T0 in FIG. 4.

The signal having a high level, which is output from the inverter 21A of FIG. 2, is supplied to each gate in the transistors M21 and M22 via the input B1 of the inverter 21B of FIG. 2. Supplying the output signal having a high level to each gate of the transistors M21 and M22 causes the p-channel transistor M21 to switch to an ‘OFF’ state and causes the n-channel transistor M22 to switch to an ‘ON’ state. Consequently, the level of a signal output from the inverter 21B of FIG. 2 shifts to a low level, so that the level of a control signal ICKZ shifts to a low level in the interval until the time T0 in FIG. 4.

As shown in FIG. 4, a power down signal PDS used for setting the sleep mode is set to a low level in the normal mode. The power down signal PDS corresponds to a sleep mode setting signal in the first embodiment. An inverted power down signal PDR having a high level is supplied to each gate of the transistors M1 and M2 of FIG. 2. As shown in FIG. 3, the inverted power down signal PDR is obtained by inverting the power down signal PDS with the inverter 22B. Supplying the inverted power down signal PDR having a high level to each gate of the transistors M1 and M2 of FIG. 2 causes the n-channel transistor M1 to switch to an ‘ON’ state and causes to the p-channel transistor to switch to an ‘OFF’ state.

The respective control signals ICKX and ICKZ of FIG. 2 are supplied to the transfer gate 23C in the master latch circuit 23 of FIG. 2, so that the transfer gate 23C becomes conductive in order to pass an input signal IS to the inverter 23A. The inverter 23A of FIG. 2 outputs an inverted signal IS1 obtained by inverting the input signal IS. The inverter 23B of FIG. 2 outputs an inverted signal obtained by inverting the inverted signal IS1.

Subsequently, at the time T0 in FIG. 4, supplying the clock signal CLK having a high level to each gate of the transistors M11 and M12 of FIG. 2 causes the p-channel transistor M11 to switch to an ‘OFF’ state and causes the n-channel transistor M12 to switch to an ‘ON’ state. Consequently, the level of the signal output from the inverter 21A of FIG. 2 shifts to a low level, so that the level of the control signal ICKX shifts to a low level.

The low level signal output from the inverter 21A of FIG. 2 is supplied to each gate of the transistors M21 and M22 via the input B1 of the inverter 21B of FIG. 2. Supplying the output signal having a low level to each gate of the transistors M21 and M22 causes the p-channel transistor M21 to switch to an ‘ON’ state and causes the n-channel transistor M22 to switch to an ‘OFF’ state. Consequently, the level of the signal output from the inverter 21B of FIG. 2 shifts to a high level. As a result, as shown in FIG. 4, the level of the control signal ICKZ shifts to a high level.

The control signal ICKX having a low level and the control signal ICKZ having a high level are supplied to the transfer gate 23D of the master latch circuit 23 of FIG. 2 and a transfer gate 31A of the signal transfer circuit 31 in the slave circuit 30, respectively. This causes the transfer gates 23D and 31A to become conductive. Consequently, the inverted IS1 is latched and the inverted signal IS1 is fed, as a transfer signal IS2, to the slave latch circuit 32 of FIG. 2 at time T1 in FIG. 4.

The inverter 32A in the slave latch circuit 32 of FIG. 2 inverts the transfer signal IS2 and an output signal OS (See FIG. 1) is generated. The output signal OS is output via the output line L2 at time T2 in FIG. 4.

Subsequently, when the level of the clock signal CLK shifts to a low level from a high level, the control signal ICLX shifts to a low level, on the other hand, the control signal ICKZ shifts to a low level. The above shift causes the transfer gate 32C in the slave latch circuit 32 of FIG. 2 to become conductive and the output signal OS is latched and output.

Such an operation, as shown in FIG. 4, wherein the input signal IS is finally converted to the output signal OS responsive to changes in the levels of clock signal CLK while being converted to the inverted signal IS1 and the transferred signal IS2 intermediately, is repeated in the normal mode.

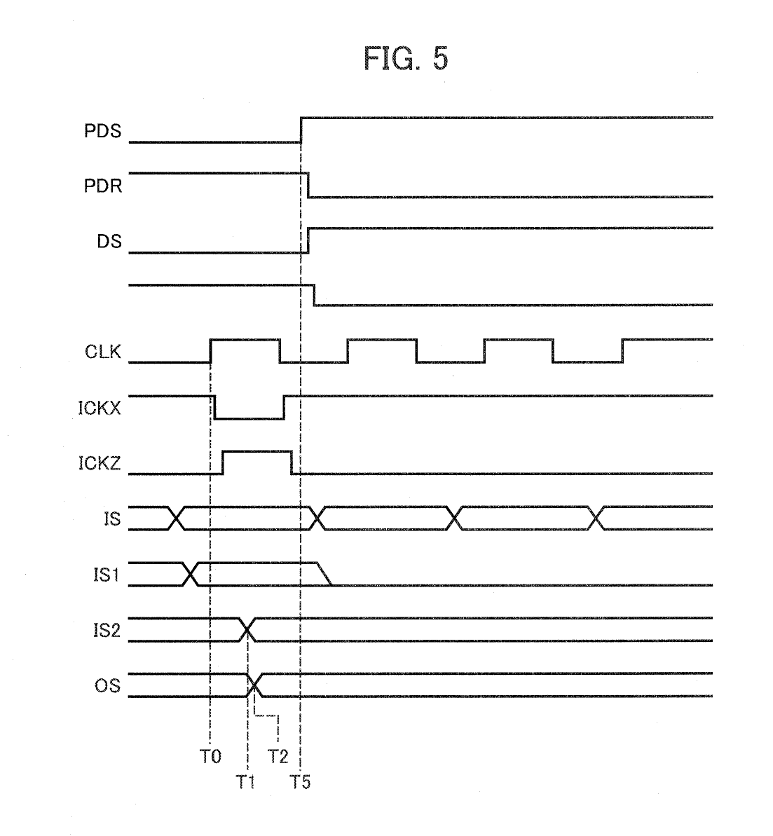

In addition, the flip-flop circuit according to the first embodiment operates in the following manner in the sleep mode. As shown in FIGS. 1 and 5, the power down signal PDS having a high level is input to the master circuit supply voltage control circuit 22 of FIG. 2 at time T5, as shown in FIG. 5, in the sleep mode. The level of the clock signal CLK at the time T5 is a low level.

As shown in FIGS. 2 and 5, after the time T5 has elapsed, the inverted power down signal PDR having a low level is supplied to the respective gates of the n-channel transistor M1 and the p-channel transistor M2 of FIG. 2.

Supplying the inverted power down signal PDR having a low level to each gate of the transistors M1 and M2 of FIG. 2 causes the n-channel transistor M1 to switch to an ‘OFF’ state and causes the p-channel transistor M2 to switch to an ‘ON’ state. Consequently, as shown in FIG. 5, the level of the control signal ICKX is kept at a high level.

Switching the p-channel transistor M2 to the ‘ON’ state results in the p-type channel transistor M21 to switch to the ‘OFF’ state and results in the n-channel transistor M22 to switch to the ‘ON’ state. Consequently, the level of the signal output from the inverter 21B of FIG. 2 shifts to a low level, and as shown in FIG. 5, the level of the control signal ICKZ is kept at the low level.

As shown in FIG. 2, the control signal ICKX having a high level and the control signal ICKZ having a low level are supplied to the transfer gate 23C of the master latch circuit 23 of FIG. 2, the transfer gate 31A of the signal transfer circuit 31 and the transfer gate 32C of the slave latch circuit 32 of FIG. 2, respectively, via a signal transfer line L3 and a signal transfer line L4.

The transfer gate 31A of FIG. 2 becomes non-conductive responsive to the control signal ICKX having a high level and the control signal ICKZ having a low level. Consequently, even if the transfer gate 23C of FIG. 2 becomes conductive responsive to the control signal ICKX having a high level and the control signal ICKZ having a low level, the inverted signal IS1 is unable to pass through the transfer gate 31A, which remains non-conductive. As a result, as shown in FIG. 5, the slave latch circuit 32 of FIG. 2 stops latching the inverted signal IS1 to itself.

In the sleep mode, the slave latch circuit 32 of FIG. 2 latches the transfer signal IS1 at the time T1 before the time T5, as well as the normal mode shown in FIG. 4.

In the sleep mode, the power down signal PDS having a high level is supplied to the master circuit supply voltage circuit 22 of FIG. 2 at the time T5 following the time T1. Subsequently, a delay signal DS having a high level, which is obtained by delaying the power down signal PDS, is supplied to the gate of the p-channel transistor M31 in the master circuit supply voltage control circuit 22 of FIG. 2.

This results in the p-channel transistor M31, which is coupled to the power supply line VDD, to switch to the ‘OFF’ state after the time T5. Consequently, the connection between the power supply line and the master latch circuit 23 is disconnected, and the supply of a power supply voltage VFF to the respective inverters 23A and 23B in the master latch circuit 23 of FIG. 2 is interrupted. Then, the p-channel transistor M31 switches to an ‘OFF’ state, and a power supply voltage VFF drops, as shown in FIG. 5.

On the other hand, the transfer gate C32 becomes conductive responsive to the control signal ICKX having a high level and the control signal ICKZ having a low level. This causes the output signal OS to be latched and output.

In the first embodiment, the control signals ICKX and ICKZ, which are obtained from the power down signal PDS, control the respective transfer gates 31A and 32C of FIG. 2 to become conductive or non-conductive, so that the output signal OS is latched and output. The delay signal DS is supplied to the gate of the p-channel M31 transistor of FIG. 2 after the control signal ICKX having a high level and the control signal ICKZ having a low level are supplied to the respective transfer gates 31A and 32C, so that the p-channel transistor M31 coupled to the power supply line VDD is switched to the ‘OFF’ state.

In the first embodiment, the control signals ICKX and ICKZ control the transfer gate 31A of FIG. 2, which is coupled to the output line L1, to become conductive or non-conductive. In the first embodiment, the delay signal DS having a high level is generated by delaying the power down signal PDS having a high level. Furthermore, the delay signal DS having a high level causes the p-channel transistor M31 of FIG. 2 to switch to the ‘OFF’ state to disconnect the connection between the power supply line VDD and the master latch circuit 23, in the first embodiment.

In the flip-flop circuit 10 in the first embodiment, the inverted power down signal PDR having a low level, which is generated based on the power down signal PDS having a high level for setting the sleep mode, is supplied to the gate of the n-channel transistor M1 and the gate of the p-channel transistor M2 in the clock generation circuit 21 of FIG. 2 and the control signal ICKX having a high level and the control signal ICKZ having a low level are generated. As described above, in the flip-flop circuit 10 in the first embodiment, the transfer signal IS2 was supplied to the slave latch circuit 32 in the slave circuit 30 and the output signal OS is latched and output.

In the flip-flop circuit 10 in the first embodiment, the inverted signal IS1, which is output from the master latch circuit 23 in the master circuit 20 of FIG. 2 based on the power down signal PDS having a high level, is supplied to the slave latch circuit 32 as the transfer signal IS2 so that the loss of the inverted signal IS1 is prevented. Furthermore, in the flip-flop circuit 10 in the first embodiment, the control signals ICKX having a high level and ICKZ having a low level are supplied to the gate of the transfer gate 31A in the signal transfer circuit 31 and the gate of the transfer gate 32 in the slave latch circuit 32. This supplies the transfer signal IS2 to the slave latch circuit 32 and supplies the delay signal DS having a high level to the gate of the p-channel transistor M31 in the master circuit supply voltage control circuit 22.

In the flip-flop circuit 10 in the first embodiment, after the transfer signal IS2 is supplied to the slave latch circuit 32, the p-channel transistor M31, which is coupled between the power supply line VDD and the master latch circuit 23, switches to the ‘OFF’ state by the delay signal DS having a high level, so that the supply of the power supply voltage VFF to the respective inverters 23A and 23B in the master latch circuit 23 is interrupted.

The flip-flop circuit 10 in the first embodiment can reduce power consumption due to the master latch circuit 23 by interrupting the supply of the power supply voltage VFF to the operation of the master latch circuit 23. In addition, the flip-flop circuit 10 in the first embodiment can prevent loss of the inverted signal IS1 by feeding the transfer signal IS2 to the slave latch circuit 32.

Since the inverted signal IS1 output from the master latch circuit 23 is supplied to the slave latch circuit 32 as the transfer signal IS2, the flip-flop circuit 10 according to the first embodiment requires no additional circuit used for latching the transfer signal IS2 other than the circuit in the flip-flop circuit 10. In consequence, since there is no need for adding a new circuit to the flip-flop circuit 10 in the first embodiment, the area occupied by the flip-flop circuit 10 can be reduced.

In the flip-flop circuit 10 according to the first embodiment, the transfer gate 31A of FIG. 2 is coupled to the output line L1 which couples the master latch circuit 23 and the slave latch circuit 32. The transfer gate 31A is set to be conductive or non-conductive based on the levels of control signals ICKX and ICKZ. In the first embodiment, when the transfer gate 31A is set to be conductive or non-conductive based on the levels of control signals ICKX and ICKZ, the inverted signal IS1 output from the master latch circuit 23 passes through the transfer gate 31A responsive to the levels of the respective control signals ICKX and ICKZ, and the inverted signal IS1 is latched, as the transfer signal IS2, to the slave latch circuit 32.

In the flip-flop circuit 10 according to the first embodiment, the transfer signal IS2 of FIG. 2 is used for supplying the inverted signal IS1, which is output from the master latch circuit 32 of FIG. 2, to the slave latch circuit 32 as the transfer signal IS2. The use of the operation characteristics of the transfer gate 31A can achieve a high-speed switching operation and a reduction in power consumption due to the high-speed switching operation.

In the method of controlling the flip-flop circuit 10 according to the first embodiment, by fixing the gate voltage of the transfer gate 31A to a high voltage level or a low voltage level responsive to the levels of the control signals ICKX and ICKZ, the transfer gate 31A can be set to be conductive or non-conductive. The use of the operation characteristics of the transfer gate 31A can achieve a high-speed switching operation and a reduction in power consumption due to the high-speed switching operation.

In the flip-flop circuit 10 according to the first embodiment, the delay control circuit 22A generates the delay signal DS by delaying the power down signal PDS. The p-channel transistor M31 coupled between the power supply line VDD and the master latch circuit 23 is switched to an ‘OFF’ state responsive to the delay signal DS. Note that the delay signal DS is generated by delaying the power down signal PDS. In the flip-flop circuit 10 according to the first embodiment, the control signals ICKX and ICKZ, which are generated based on the power down signal PDS, cause the transfer gate 31A to become non-conductive and cause the transfer gate 32C to become conductive. According to this operation, the inverted signal IS1 is supplied to the slave latch circuit 32 as the transfer signal IS2 and, subsequently, the p-channel transistor M31, which is coupled between the power supply line VDD 32 and the master latch circuit 23, switches to the ‘OFF’ state by the delay signal DS, which is generated by delaying the power down signal PDS, so that the supply of the power supply voltage VFF to the master-latch circuit 23 is interrupted. The flip-flop circuit 10 according to the first embodiment can thereby prevent the loss of the inverted signal IS1 without interrupting the power supply voltage VFF to the master latch circuit 23, before feeding the transfer signal IS2 to the slave latch circuit 32.

In the flip-flop circuit 10 according to the first embodiment, since the p-channel transistor M31 of FIG. 2 is coupled between the power supply line VDD and the master latch circuit 23, an ‘ON’ state or the ‘OFF’ state of the p-channel transistor M31 can be controlled responsive to the signal level of the delay signal DS. The use of the operation characteristics of the p-channel transistor can achieve a reduction in power consumption.

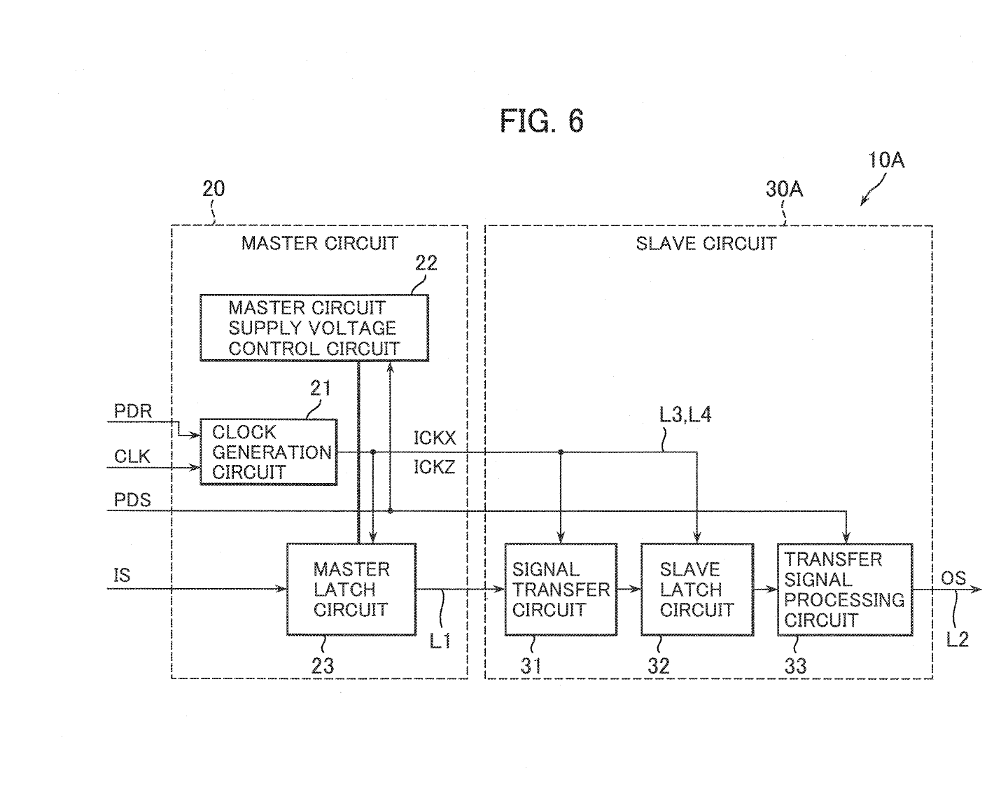

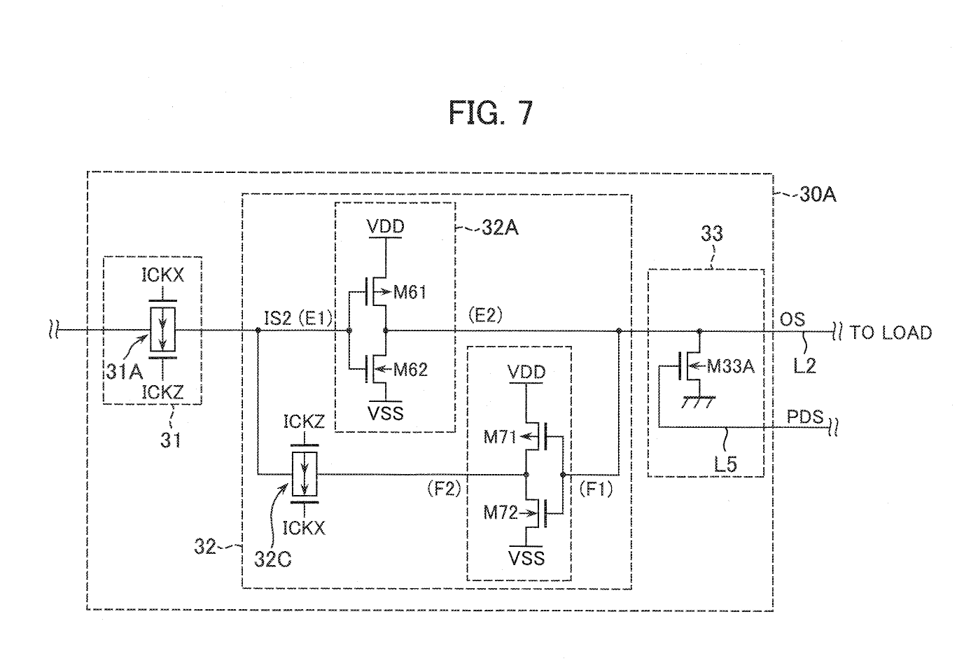

A second embodiment of the present invention will be described with reference to FIGS. 6 and 7. The same elements as in the foregoing first embodiment are designated by the same reference numbers, and thus, their description is omitted. A flip-flop circuit 10A shown in FIG. 6 includes a slave circuit 30A instead of the slave circuit 30 in the first embodiment. The slave circuit 30A further includes a signal transfer circuit 31, a slave latch circuit 32 and a transfer signal processing circuit 33.

The transfer signal processing circuit 33 includes an n-channel transistor M33A as shown in FIG. 7. A drain of the n-channel transistor M33A is coupled to an output line L2. A source of the N-type transistor 33A is coupled to a ground. A gate of the n-channel transistor 33A is coupled to a signal transfer line L5.

Next, operation of the flip-flop circuit 10A according to the second embodiment will be described. Certain aspects of the operation of the flip-flop circuit 10A will be omitted as they correspond to those of the flip-flop circuit 10. The flip-flop circuit 10A operates in a sleep mode in the following manner.

In the sleep mode, a power down signal PDS having a high level is supplied to the gate of the n-channel transistor M33A via the signal transfer line L5. Supplying the power down signal PDS to the gate of the n-channel transistor M33A causes the n-channel transistor M33A to switch to an ‘ON’ state. Therefore, the output line L2 is coupled to ground via the n-channel transistor M33A having a conductive state. After coupling, a level of an output signal OS on the output line L2 becomes a low level. In the second embodiment, the output signal OS having a low level is output to a load which operates according to positive logic.

In the flip-flop circuit 10A according to the second embodiment, the transfer signal processing circuit 33 in the slave circuit 30A causes the p-channel transistor M33A, which is coupled between the output line L2 and the ground, to switch to the ‘ON’ state based on the power down signal PDS having a high level and causes the level of the output signal OS on the output line L2 to shift to a low level.

In the flip-flop circuit 10A according to the second embodiment, when the sleep mode is set responsive to the power down signal PDS having a high level, the level of the output signal OS is set to a low level. This prevents the output signal OS having a high level from being transmitted to the load, which operates according to the positive logic.

Consequently, the flip-flop circuit 10A can prevent the load, which operates according to positive logic, from being operated by the output signal OS having a high level in the sleep mode.

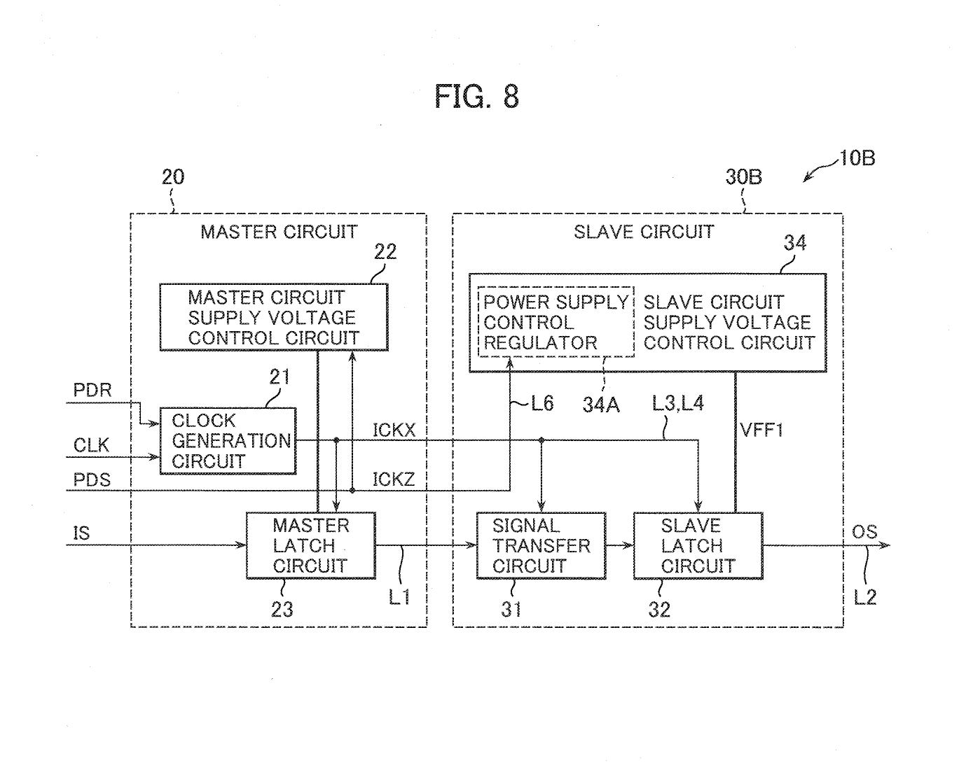

A third embodiment of the present invention will be described with reference to FIG. 8. The same elements as in the foregoing first and the second embodiments are designated by the same reference numerals to reduce or omit their corresponding description. A flip-flop circuit 10B shown in FIG. 8 includes a slave circuit 30B instead of the slave circuit 30A. The slave circuit 30B includes a signal transfer circuit 31, a slave latch circuit 32 and a slave circuit supply voltage control circuit 34. The slave circuit supply voltage control circuit 34 further includes a power supply control regulator 34A.

Next, operation of the flip-flop circuit 10B according to the second embodiment will be described. Certain aspects of the operation of the flip-flop circuit 10B will be omitted as they correspond to those of the flip-flop circuit 10 and 10A. The flip-flop circuit 10B operates in the following manner in a sleep mode.

In the sleep mode, a power down signal PDS having a high level is supplied to the power supply control regulator 34A via a signal transfer line L6. When the power down signal PDS having a high level is supplied to the power supply control regulator 34A, the power supply control regulator 34A supplies a power supply voltage VFF1 to the slave latch circuit 32. A value of the power supply voltage VFF1 is set so that it is enough to latch an output signal OS to an output.

A voltage value necessary for latching the output signal OS to the output is lower than a voltage value of the power supply voltage, which the slave circuit supply voltage control circuit 34 supplies to the slave latch circuit 32, in a normal mode.

In the flip-flop circuit 10B in the third embodiment, the slave circuit supply voltage control circuit 34 supplies, responsive to the power down signal PDS having the high level, the power supply voltage VFF1 sufficient for the slave latch circuit 32 to latch the output signal OS. This allows the value of the power supply voltage VFF to be set to a value lower than a voltage value which the slave latch circuit 32 requires in the normal mode.

In the flip-flop circuit 10B in the third embodiment, the power supply voltage VFF1, which the slave circuit supply voltage control circuit 34 supplies to the slave latch circuit 32, is set to the value lower than the voltage value which is required by the slave latch circuit 32 in the normal mode. This reduces power consumption of the slave circuit supply voltage control circuit 34 in the sleep mode compared with the power consumption of the slave circuit supply voltage control circuit 34 in the normal mode.

Consequently, the flip-flop circuit 10B in the third embodiment can reduce the power consumption in the sleep mode compared with the power consumption in the normal mode, while on the other hand, it allows the slave latch circuit 32 to latch the output signal OS.

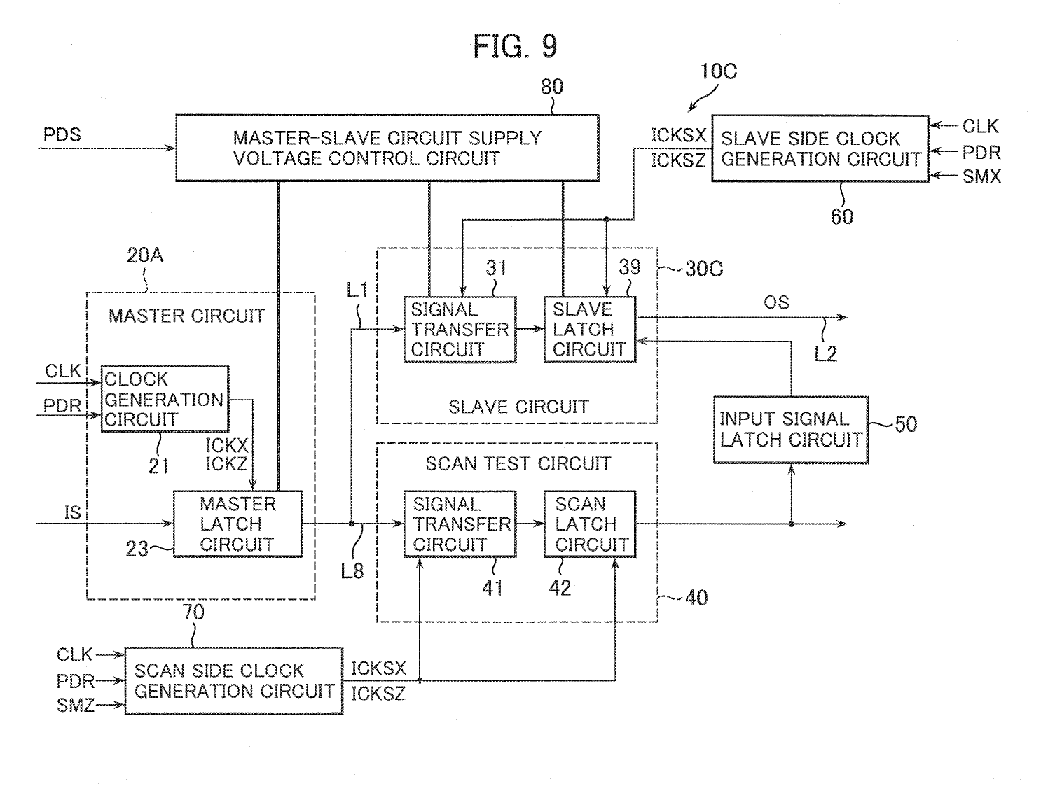

A fourth embodiment of the present invention will be described with reference to FIGS. 9 through 15. The same elements as in the foregoing first through third embodiments are designated by the same reference numbers to reduce or omit the description. A flip-flop circuit 10C shown in FIG. 9 includes a master circuit 20A, a slave circuit 30C, a scan test circuit 40, an input signal latch circuit 50, a slave-side clock generation circuit 60, a scan-side clock generation circuit 70 and a master circuit-slave circuit supply voltage control circuit 80.

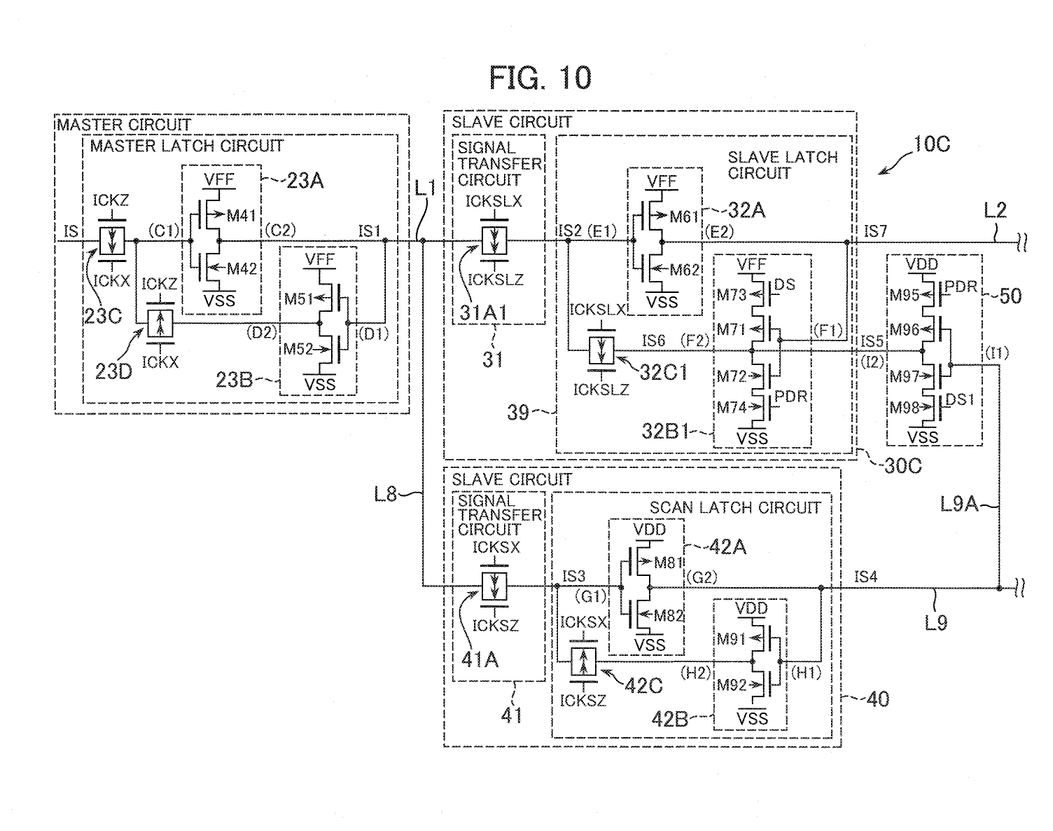

In addition, the master circuit 20A includes the clock generation circuit 21 and the master latch circuit 23. The clock generation circuit 21 is not shown in FIG. 10.

The slave circuit 30C includes a signal transfer circuit 31 and a slave latch circuit 39. The signal transfer circuit 31 includes a transfer gate 31A1 as shown in FIG. 10.

The slave latch circuit 39 includes an inverter 32B1 instead of the inverter 32B provided in the slave latch circuit 32 of FIG. 2. As shown in FIG. 10, the inverter 32B1 includes a plurality of p-channel transistors M71 and M73 and a plurality of n-channel transistors M72 and M74.

A drain of the p-channel transistor M73 is coupled to a source of the p-channel transistor M71. A drain of the p-channel transistor M71 is coupled to a drain of the n-channel transistor M72. A source of the n-channel transistor M72 is coupled to a drain of the n-channel transistor M74. A ground potential VSS is supplied to a source of the n-channel transistor M74.

The scan test circuit 40 includes a signal transfer circuit 41 and a scan latch circuit 42. As shown in FIG. 10, a signal transfer circuit 41 includes a transfer gate 41A.

The scan test circuit 42 includes an inverter 42A, an inverter 42B and a transfer gate 42C. An input G1 of the inverter 42A is coupled to an output C2 of the inverter 23A via the signal transfer circuit 41 coupled to an output line L8. As shown in FIG. 10, the output line L8 is coupled in parallel to the output line L1.

An output G2 of the inverter 42A is coupled to an output line L9 and an input H1 of the inverter 42B. The inverter 42B includes a p-channel transistor M91 and an n-channel transistor M92. An output H2 of the inverter 42B is coupled to the input G1 of the inverter 42A.

The input signal latch circuit 50 includes a plurality of p-channel transistors M95 and M96 and a plurality of N-type transistors M97 and M98. A source of the p-channel transistor M95 is coupled to a power supply line VDD. A drain of the p-channel transistor M95 is coupled to a source of the p-channel transistor M96.

A drain of the p-channel transistor M96 is coupled to a drain of the n-channel transistor M97. A source of the n-channel transistor M97 is coupled to a drain of the n-channel transistor M98. A ground potential VSS is supplied to a source of the n-channel transistor M98.

An input I1 of the input signal latch circuit 50 is coupled to the output line L9 through an input line L9A. The input I1 of the input signal latch circuit 50 is also coupled to gates of the p-channel transistor M96 and the n-channel transistor M97, respectively.

A connection node of the drain of the p-channel transistor M96 and the drain of the n-channel transistor M97 is coupled to an output I2 of the input signal latch circuit 50. The output I2 of the input signal latch circuit 50 is coupled to an input E1 of the inverter 32A in the slave latch circuit 39 via the transfer gate 32C1.

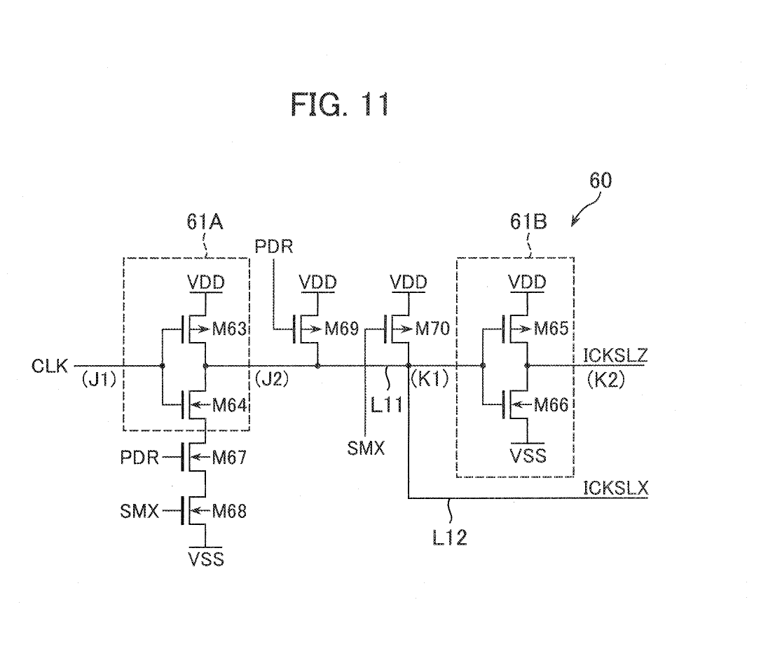

As shown in FIG. 11, the slave-side clock generation circuit 60 includes an inverter 61A, an inverter 61B, a plurality of n-channel transistors M67 and M68 and a plurality of p-channel transistors M69 and M70.

The inverter 61A includes a p-channel transistor M63 and an n-channel transistor M64. A source of the n-channel transistor M64 is coupled to a drain of the N-type transistor M67. A source of the n-channel transistor M67 is coupled to a drain of the n-channel transistor M68. The ground potential VSS is supplied to a source of the n-channel transistor M68. In FIG. 11, a reference symbol J1 indicates an input to the inverter 61A and a reference symbol J2 indicates an output from the inverter 61A.

The output J2 from the inverter 61A is coupled to an input K1 to the inverter 61B. The inverter 61B includes a p-channel transistor M65 and an n-channel transistor M66. A reference symbol K2 indicates an output from the inverter 61B.

The output J2 from the inverter 61A is coupled to the input K1 to the inverter 61B via a signal transfer line L11. A drain of p-channel transistor M69 and a drain the p-channel transistor M70 are coupled to the signal transfer line L11, respectively. As shown in FIG. 11, the signal transfer line L11 is coupled to an output line L12.

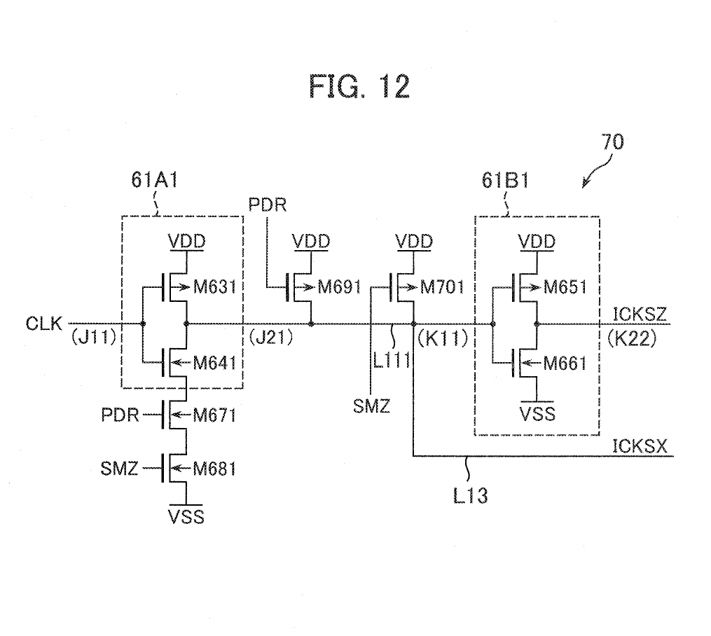

As shown in FIG. 12, the scan-side clock generation circuit 70 includes an inverter 61A1, an inverter 61B1, a plurality of n-channel transistors M671 and M681, and a plurality of n-channel transistor M691 and M701. As shown in FIG. 12, a signal transfer line L111 is coupled to an output line L13.

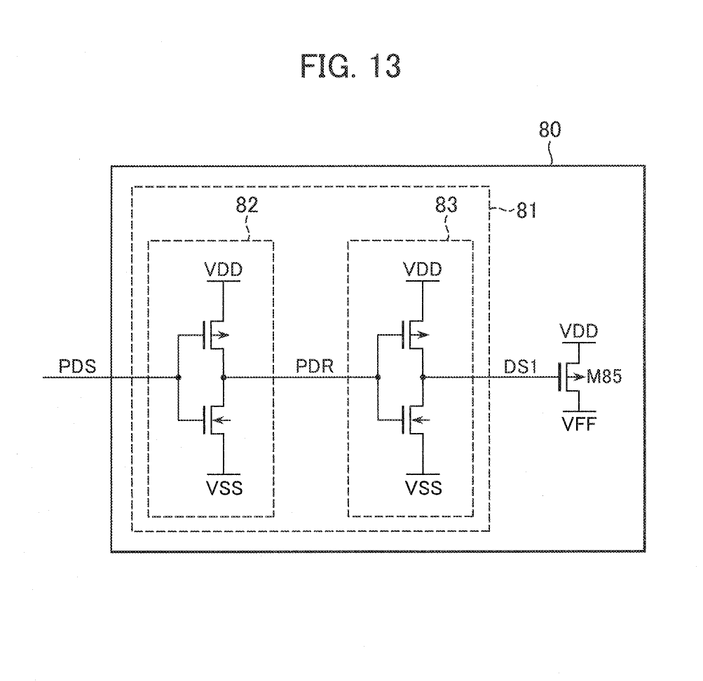

As shown in FIG. 13, the master circuit-slave circuit supply voltage control circuit 80 includes a delay control circuit 81 and a p-channel transistor M85. An output of the delay control circuit 81 is coupled to a gate of the p-channel transistor M85. A power supply voltage is supplied to a source of the p-channel transistor M85 via the power supply line VDD. The delay control circuit 81 includes two inverters 82 and 83 coupled in a multistage manner.

Next, operation of the flip-flop circuit 10C in the fourth embodiment will be described. The flip-flop circuit 10C operates in such a manner that prevents a loss of an input signal IS when the flip-flop circuit 10C is switched to a sleep mode from a normal mode.

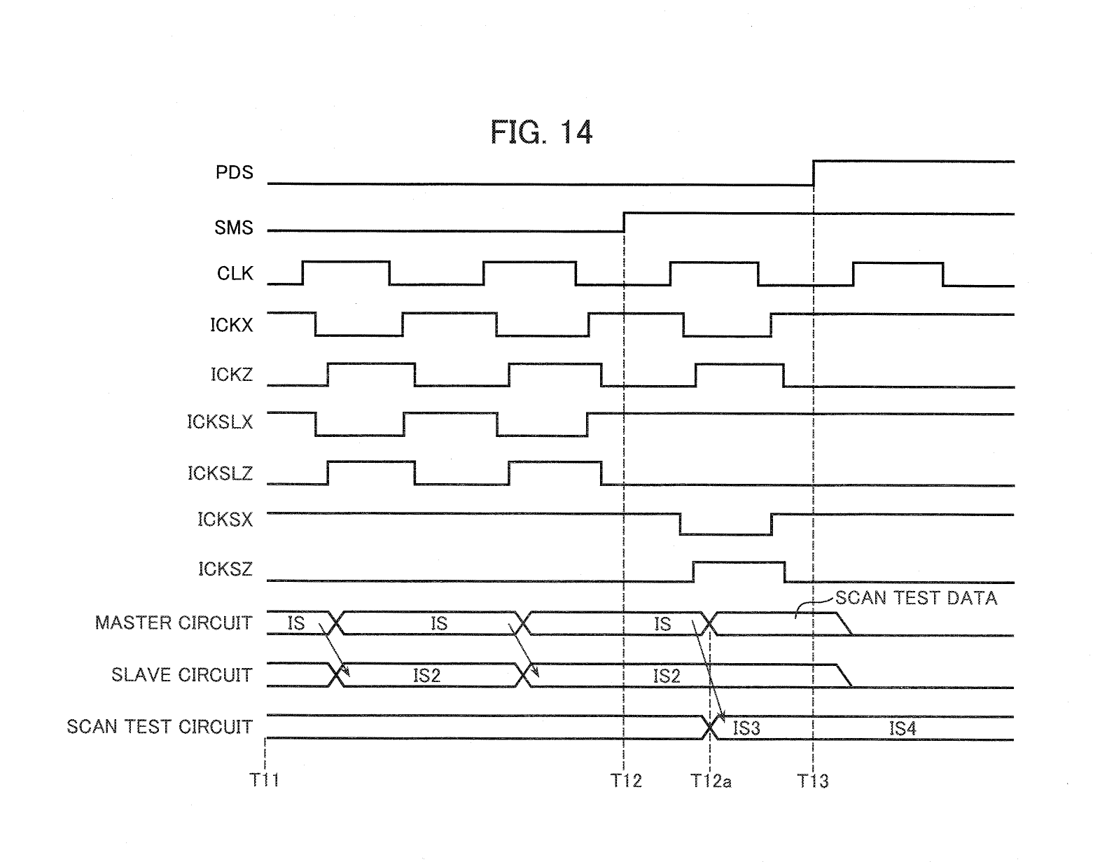

In the normal mode, as shown in FIG. 14, a level of a power down signal PDS is set to a low level which is the same as the case of the first embodiment. The level of the power down signal PDS is set to a low level in an interval between time T11 to time T12, so that an inverted power down signal PDR having a high level is supplied to a gate of the n-channel transistor M1 (see FIG. 2) and the above-described gate of a p-channel transistor M2 (see FIG. 2). Consequently, the n-channel transistor M1 switches to an ‘ON’ state and the p-channel transistor M2 switches to an ‘OFF’ state.

As described in the first embodiment, when a level of a clock signal CLK is a low level, a level of a control signal ICKX shifts to a high level and a level of a control signal ICKZ 9 shifts to a low level in the interval between the time T11 and the time T12.

On the other hand, similar to the first embodiment, when the level of the clock signal CLK is a high level, the level of the control signal ICKX shifts to a low level and the level of the control signal ICKZ shifts to a high level, in the interval between the time T11 and the time T12.

A scan test signal SMS used for setting a scan mode is set to a low level in the normal mode. Note that a scan test is conducted for the purpose of checking an interconnection after circuit board implementation or for the purpose of checking a circuit operation. As shown in FIG. 14, in the interval between the time T11 and the time T12, a level of the scan test signal SMS is set to a low level, and a level of a first inverted scan test signal SMX is set to a high level. Note that the first scan test signal SMX is obtained by inverting the scan test signal SMS having a low level by an inverter (not shown).

As shown in FIG. 11, the first inverted scan test signal SMX having the high level is supplied to a gate of the n-channel transistor M68 and a gate of the p-channel transistor M70. Therefore, the n-channel transistor M68 is switched to an ‘ON’ state and the p-channel transistor M70 is switched to an ‘OFF’ state.

In addition, as shown in FIG. 11, the inverted power down signal PRD having a high level is supplied to a gate of n-channel transistor M67 and a gate of the p-channel transistor M69 in the interval between the time T11 and the time T12 of FIG. 14. Therefore the n-channel transistor M67 is switched to an ‘ON’ state and the p-channel transistor M69 is switched to an ‘OFF’ state.

As shown in FIGS. 11 and 14, the clock signal CLK having a low level from the input J1 of the inverter M61A in the slave-side clock generation circuit 60 is input in the interval between the time T11 and the time T12. Therefore, the p-channel transistor M63 switches to an ‘ON’ state, a level of a control signal ICKSLX shifts to a high level and a level of a control signal ICKSLZ shifts to a low level. Note that, the n-channel transistor M64 switches to an ‘OFF’ state by receiving the clock signal CLK having a low level.

On the other hand, inputting the clock signal CLK having a high level from the input J1 of the inverter 61A in the slave-side clock signal generation circuit 60, the p-channel transistor M63 switches to an ‘OFF’ state, the level of the control signal ICKSLX shifts to a low level, and the level of the control signal ICKSLZ shifts to a high level. Note that the n-channel transistor M64 switches to an ‘ON’ state by receiving the clock signal CLK having a high level.

An inverter (not shown) in the flip-flop circuit 10C of FIG. 10 inverts the first inverted scan test signal SMX to generate a second inverted scan test signal SMZ. The above-described inverter inverts the first inverted scan test signal SMX having a high level to generate a second inverted scan test signal SMZ having a low level in the interval between the time T11 and the time T12 of FIG. 14.

As shown in FIG. 12, the second scan test signal SMZ having a low level is supplied to a gate of the n-channel transistor M681 and a gate of the p-channel transistor M701, respectively. In consequence, the n-channel transistor M681 switches to an ‘OFF’ state and the p-channel transistor M701 switches to an ‘ON’ state.

Each gate voltage of the transistors M671 and M691 in FIG. 12 is fixed at a high voltage level. In consequence, like as shown in FIG. 11 n-channel transistor M671 switches to an ‘ON’ state and the p-channel transistor M691 switches to an ‘OFF’ state.

A drain of the p-channel transistor M701 with the ‘ON’ state is coupled to the signal transfer line L111, in the interval between the time T11 and the time T12 of FIG. 14, in the scan-side clock generation circuit 70 shown in FIG. 12. In consequence, as shown in FIG. 14, a control signal ICKSX output from the output line L13 is kept at a high level regardless of changes of the clock signal CLK in the interval between the time T11 and the time T12. The inverter 61B1, on the other hand, inverts the control signal ICKSX having a high level to generate a control signal ICKSZ having a low level in the interval between the time T1 and the time T12.

In the flip-flop circuit 10C of FIG. 10, in the same manner as the first embodiment, when the clock signal CLK shift from a low level to a high level, the transfer gate 23D in a master latch circuit 23 and the signal transfer circuit 31 in the slave circuit 30C become conductive responsive to the control signals ICKX, ICKZ, ICKSLX, and ICKSLZ, in the interval between the time T11 and the time T12 of FIG. 14. The inverter 23A in master latch circuit 23 thereby outputs an inverted signal IS1 to the slave latch circuit 39. The inverted signal IS1 is latched to the slave latch circuit 32 as a transfer signal IS2.

As shown in FIG. 14, in the fourth embodiment, the level of the scan test signal SMS is set to a high level at the time T12 to switch a mode to the normal mode from the scan mode. When the level of the scan test signal SMS is set to a high level, the level of the first inverted scan test signal SMX is set to a low level.

As shown in FIG. 11, when the first inverted scan test signal SMX having a low level is supplied to the transistor M70, the p-channel transistor M70 switches to an ‘ON’ state.

The drain of the p-channel transistor M70 that is in the ‘ON’ state is coupled to the signal transfer line L11. As shown in FIG. 14, the control signal ICKSLX output from the signal transfer line L12 is kept at a high level regardless of the changes of the clock signal CLK after the time T12. On the other hand, the inverter 61B inverts the control signal ICKSLX having a high level to generate the control signal ICKSLZ having a low level.

The control signal ICKSLX having a high level and the control signal ICSKLZ having a low level cause the transfer gate 31A1 of the signal transfer circuit 31 in the slave circuit 30C to become non-conductive. Therefore, the inverted signal IS1 is not latched to the slave latch circuit 32.

The flip-flop circuit 10C operates in the following manner in an interval between the time T12 and time T13 in FIG. 14. In the interval between the time T12 and the time T13, the inverted power down signal PDR having a high level is supplied to the gates of the n-channel transistor M671 and p-channel transistor M691 shown in FIG. 12, and the second inverted scan test signal SMZ having a high level is supplied to the n-channel transistor M681 and the p-channel transistor M701. This causes the transistors M691 and M701 coupled to the signal transfer line L111 to switch to the ‘OFF’ state.

In the scan-side clock generation circuit 70 of FIG. 12, in the interval between the time T12 and the time T13, when the clock signal CLK having a high level is input from the input J11 of the inverter 61A1, the inverted clock signal having a low level is output from the output J21 of the inverter 61A1 to the signal transfer line L111. This causes the level of the control signal ICKSX output from the input line L13 to shift to a low level. At this time, the inverter 61B1 inverts the control signal ICKSX having a low level to generate the control signal ICKSZ having a high level.

The control signals ICKSX having a low level and ICSKZ having a high level cause the transfer gate 41A of the signal transfer circuit 41 in the scan test circuit 40 of FIG. 10 to become conductive. As a result, the input signal IS1 is fed, as a transfer signal IS3, to the scan test circuit 40, at time T12a (see FIG. 14). The time T12a indicates a point of time after a given interval has elapsed from a point of time when the level of the clock signal CLK shifts to the high level after the time T12. As shown in FIG. 14, the master latch circuit 23 latches scan test data to the output at the time T12a.

In the scan test circuit 40 of FIG. 10, the inverter 42A inverts the transfer signal IS3 to generate a transfer signal IS4. The transfer signal IS4 is input to the input signal latch circuit 50 via the output line L9 and the input lines L9A.

As shown in FIG. 14, in the forth embodiment, the mode is switched from the scan mode to the sleep mode by setting the power down signal PDS to a high level at the time T13.

As shown in FIG. 13, after the power down signal PDS having a high level is input to the master circuit-slave circuit supply voltage control circuit 80, a delay signal DS1 having a high level, which is generated by delaying the power down signal PDS, is supplied to the gate of the p-channel transistor M85 in the master circuit slave circuit supply voltage control circuit 80 at the time T13. Therefore, the p-channel transistor M85 coupled to the power supply line VDD switches to an ‘OFF’ state, after the time T13.

As a result of the above operation, a connection between the power supply line VDD and the master latch circuit 23 of FIG. 10 and a connection between power supply line VDD and the slave latch circuit 39 of FIG. 10 are disconnected. As shown in FIG. 10, according to the above operation, the supply of the power supply voltage VFF to the respective inverters 23A and 23B and the supply of the power supply voltage VFF to the respective inverters 32A and 32B1 are interrupted. Therefore, as shown in FIG. 14, the input signal IS and the transfer signal IS2 disappear because the power supply voltage VFF cannot be kept at the voltage which is required to latch signals.

When the level of power down signal PDS is set to a high level, the scan-side clock generation circuit 70 of FIG. 12 generates the control signal ICLSX having a high level and the control signal ICKSZ having a low level, as shown in FIG. 14. The transfer gate 42C becomes conductive by the control signal ICLSX having a high level and the control signal ICKSZ having a low level and the transfer signal IS4 is latched and output.

At this point in time, the inverted power down signal PDR having a low level is supplied to a gate of the p-channel transistor M95 in the input signal latch circuit 50 of FIG. 10. On the other hand, the delay signal DS1 having a high level is supplied to a gate of the n-channel transistor M98 in the input signal latch circuit 50 of FIG. 10. The p-channel transistor M95 is switched to an ‘ON’ state. The n-channel transistor M95 is also switched to an ‘ON’ state. The input signal latch circuit 50 of FIG. 10 latches the transfer signal IS4 in the sleep mode.

When the inverted power down signal PDR having a low level is supplied to a gate of the p-channel transistor M2 in the clock generation circuit 21 of FIG. 9, the clock generation circuit 21 generates the control signal ICKX having a high level and the control signal ICKZ having a low level shown in FIG. 14. In addition, when the inverted power down signal PDR having a low level is supplied to the gate of the n-channel transistor M67 in the slave-side clock generation circuit 60 of FIG. 11, the slave-side clock generation circuit 60 generates the control signal ICKSLX having a high level and the control signal ICKSLZ having a low level shown in FIG. 14.

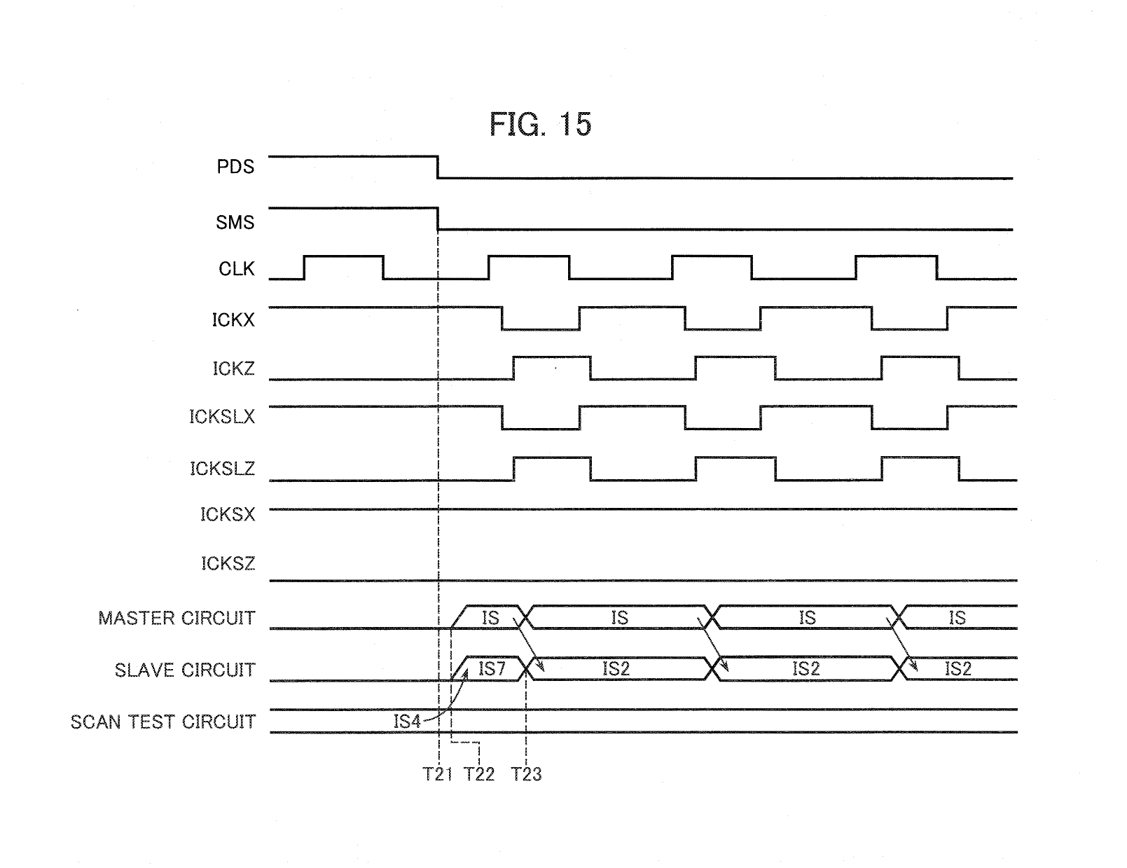

FIG. 15 is a timing chart of the flip-flop circuit 10C of FIG. 10 when changing the mode of the flip-flop circuit to the normal mode from the sleep mode. In the flip-flop circuit, the level of the power down signal PDS is set to a low level and the level of the scan test signal SMS is set to a low level at time T21. The mode is switched to the normal mode from the sleep mode.

The control signal ICKSLX having a high level and the control signal ICKSLZ having a low level are supplied to the transfer gate 32C1 in the slave latch circuit 39 of FIG. 10 at time T22 following the time T21. Therefore, the transfer gate 32C1 becomes conductive.

In the slave latch circuit 39 of FIG. 10, the inverter 32B1 inverts an inverted transfer signal IS5, which is generated by inverting the transfer signal IS4, to generate an inverted transfer signal IS6. Then, the inverter 32A further inverts the inverted transfer signal IS6 to generate an inverted transfer signal IS7. The inverted transfer signal IS7 is output from the output line L2.

In addition, the control signal ICKX having a high level and the control signal ICKZ having a low level low are supplied to a transfer gate 23C in the master latch circuit 23 of FIG. 10 at the time T22. Therefore, the transfer gate 23C becomes conductive and the input signal IS is latched to the master latch circuit 23.

Then, similar to the operation in the normal mode as shown in FIG. 14, the input signal IS is converted to the transfer signal IS2 after the input signal IS is inverted to the inverted signal IS1 and the transfer signal IS 2 is latched to the slave circuit 32. In the flip-flop circuit 10C according to the fourth embodiment, as shown in FIG. 15, the slave circuit 32 repeatedly latches the input signal IS as the transfer signal IS2, responsive to the change of the clock signal CLK from a low level to a high level.

In the flip-flop circuit 10C according to the fourth embodiment, the output line L8, which is coupled in parallel to the output line L1, is coupled between the master latch circuit 23 of FIG. 10 and the scan latch circuit 42 of FIG. 10. The transfer gate 41A coupled to the output line L8 is configured so that the transfer gate 41A is set to a conductive or non-conductive state responsive to the levels of the control signals ICKSX and ICKSZ. The levels of the control signals ICKSX and ICKSZ are changed responsive to the levels of the second inverted scan test signal SMZ supplied to the scan-side clock generation circuit 70 of FIG. 12.

In the fourth embodiment, when setting the transfer gate 41A to a conductive or non-conductive state responsive to the levels of the control signals ICKSX and ICKSZ, the inverted signal IS1 output from the master latch circuit 23 of FIG. 10 passes through the transfer gate 41A of FIG. 10 and can be latched into the scan latch circuit 42 of FIG. 2.

Consequently, the flip-flop circuit 10C according to the fourth embodiment can use the scan latch circuit 42 as a latch circuit for latching the transfer signal IS3, which is different from the scan test data.

In the flip-flop circuit 10C according to the fourth embodiment, after the scan latch circuit 42 of FIG. 9 latches the input signal IS1, as the transfer signal IS3, the master circuit-slave circuit supply voltage control circuit 80 of FIG. 9 interrupts the supply of the power supply voltage VFF to the master latch circuit 23 of FIG. 9 and the slave latch circuit 39 of FIG. 9, responsive to the power down signal PDS having the high level.

In the flip-flop circuit 10C according to the fourth embodiment, the master circuit-slave circuit supply voltage control circuit 80 interrupts the supply of the power supply voltage VFF to the master latch circuit 23 and the slave latch circuit 39 after the input signal IS latched to the master latch circuit 23 is latched to the scan latch circuit 42.

Consequently, the flip-flop circuit 10C according to the fourth embodiment can prevent the loss of input signal IS while the flip-flop circuit 10C reduces the power consumption of the slave latch circuit 39 and the master latch circuit 23.

In the flip-flop circuit 10C according to the fourth embodiment, the input line L9A of FIG. 10 is coupled between the output line L9, which is coupled to the scan latch circuit 42, and the slave latch circuit 39. The input line L9A of FIG. 10 is coupled to the input signal latch circuit 50.

The input signal latch circuit 50 of FIG. 10 latches the transfer signal IS4 responsive to the inverted power down signal PDR having the low level, which is obtained from the power down signal PDS having the high level, and the delay signal DS1 having the high level, which is obtained from the power down signal PDS having the high level.

In the flip-flop circuit 10C according to the fourth embodiment, since the input signal latch circuit 50 of FIG. 10 latches the transfer signal IS4 responsive to the power down signal PDS for setting the sleep mode, the transfer signal IS4 can be transferred to the slave latch circuit 39 without the loss of transfer signal IS4 in the sleep mode.

In the flip-flop circuit 10C according to the fourth embodiment, the delay control circuit 81 of FIG. 13 generates the delay signal DS1 obtained by delaying the power down signal PDS to switch the p-channel transistor M85 of FIG. 13, which couples the power supply line VDD to the master latch circuit 23 and the slave latch circuit 39, to the ‘OFF’ state responsive to the delay signal DS1.

In the flip-flop circuit 10C according to the fourth embodiment, the flip-flop circuit 10C can simultaneously interrupt the supply of the power supply voltage to the master latch circuit 23 of FIG. 9 and the slave latch circuit 39 of FIG. 9 by switching the p-channel transistor M85 of FIG. 13, which couples the power supply line VDD to the master latch circuit 23 and the slave latch circuit 39, responsive to the power down signal PDS.

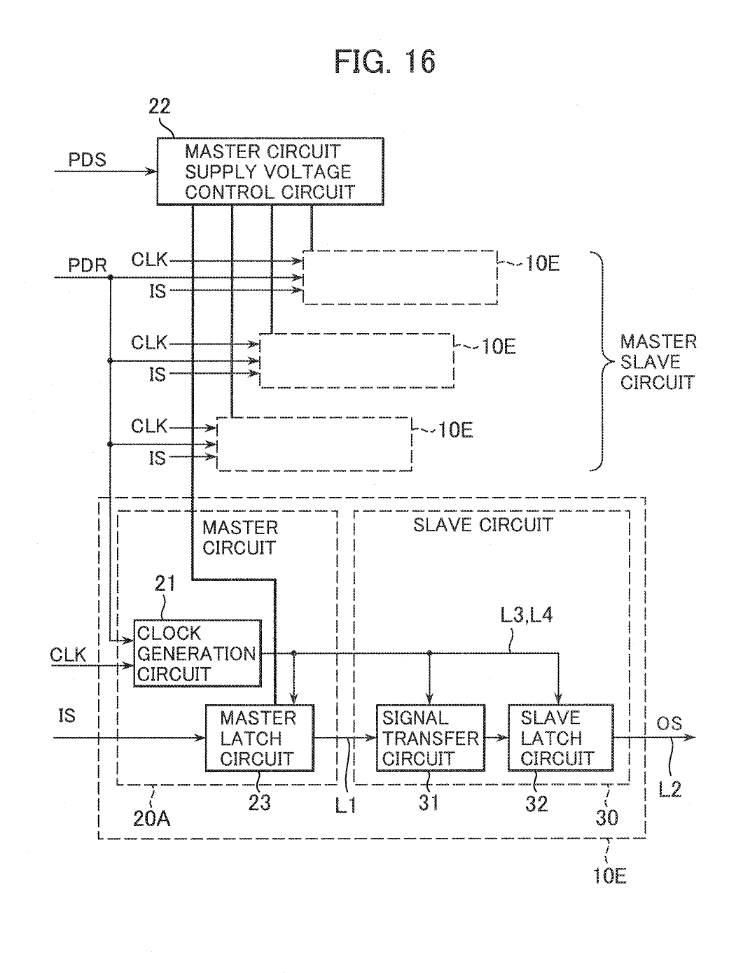

The present invention is not limited to the details of the embodiments described above, and various modifications and improvements can be applied without departing from the spirit and scope of the invention. For example, as shown in FIG. 16, in a flip-flop circuit in a fifth embodiment, a plurality of (e.g., four) master-slave circuits 10E, each of which has a master circuit 20A and a slave circuit 30, are provided and the plurality of master-slave circuits 10E are commonly coupled to a master circuit supply voltage control circuit 22. Note that the same elements as in the foregoing first through fourth variations are designated by the same reference numbers to reduce or omit the description in FIG. 16.

In the fifth embodiment shown in FIG. 16, no additional master circuit supply voltage control circuit is required with respect to each master-slave circuit 10E because the master-slave circuits 10E are commonly coupled to the master circuit supply voltage control circuit 22. The fifth embodiment shown in FIG. 16 is different from a case where the discrete master circuit supply voltage control circuits are provided with respect to each of the master-slave circuits 10E. That is, according to the fifth embodiment, an area, which is occupied by the master circuit supply voltage control circuit 22, can be reduced by sharing the master circuit supply voltage control circuit 22 coupled to the respective master-slave circuits 10E.

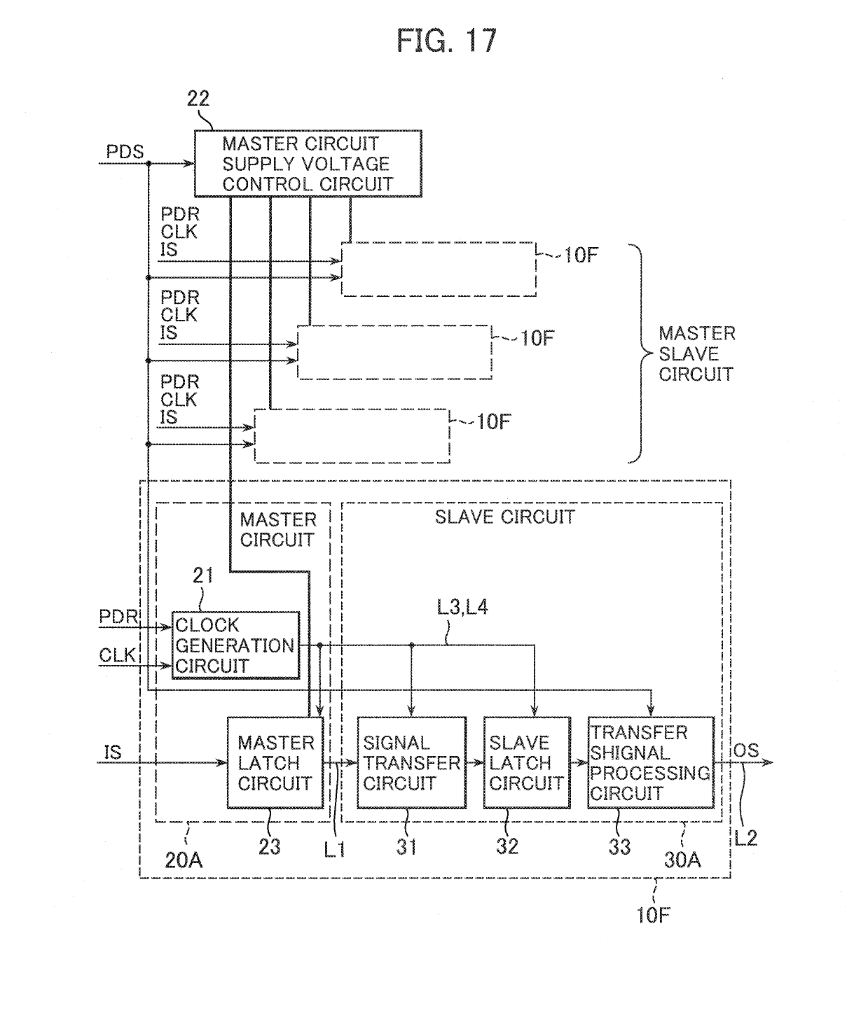

In a sixth embodiment as shown in FIG. 17, a plurality of (e.g., four) master-slave circuits 10F, each of which includes a master circuit 20A and a slave circuit 30A, are provided and the plurality of master-slave circuits 10F are commonly coupled to a master circuit supply voltage control circuit 22. Note that the same elements as in the foregoing first through fifth embodiments are designated by the same reference numbers to reduce or omit the description in FIG. 17.

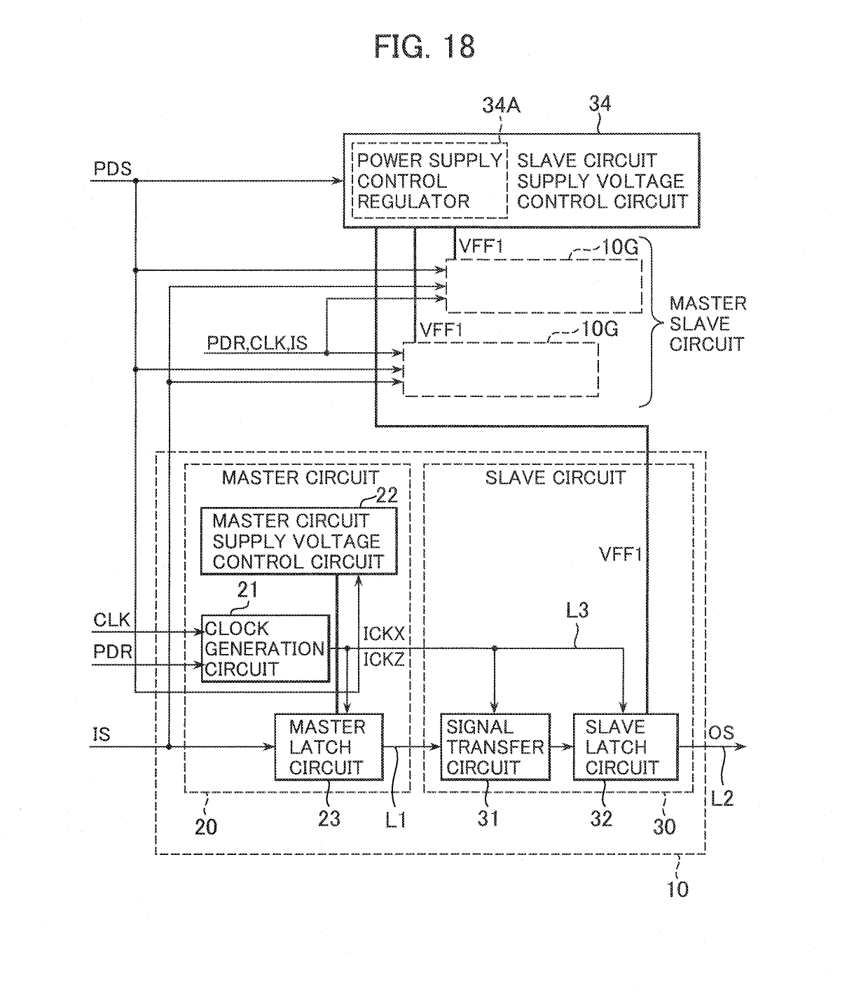

Moreover, in a seventh embodiment as shown in FIG. 18, a plurality of (e.g., three) master-slave circuits 10G, each of which a master circuit 20 and a slave circuit 30, and the plurality of master-slave circuits 10G are commonly coupled to a master circuit supply voltage control circuit 34. Note that the same elements as in the foregoing first and third embodiments are designated with the same reference numbers to reduce or omit the description in FIG. 18

In the seventh embodiment shown in FIG. 18, since a slave circuit supply voltage control circuit 34 is commonly coupled to master-slave circuits 10G, no additional slave circuit supply voltage control circuit 34 is necessary with respect to each master-slave circuit 10. The seventh embodiment shown in FIG. 18 is different from a case where the discrete slave circuit voltage supply control circuits are provided with respect to each master-slave circuit 10.

That is, in the flip-flop circuit according to the seventh embodiment, an area, which is occupied by the slave circuit supply voltage control circuit 34, can be reduced by sharing the slave circuit supply voltage control circuit 34 coupled to the respective master-slave circuits 10E.

Exemplary embodiments of the present invention have now been described in accordance with the above advantages. It will be appreciated that these examples are merely illustrative of the invention. Many variations and modifications will be apparent to those skilled in the art.

What is claimed is:

1. A master-slave circuit comprising:
a master circuit having input data stored therein;
a storage unit that receives the input data in response to a sleep mode setting signal that sets a sleep mode, and that stores the input data; and
a first control unit that interrupts the supply of a power supply voltage to the master circuit after the input data is stored in the storage unit.

2. The master-slave circuit according to claim 1, further comprising:
a slave circuit that includes the storage unit.

3. The master-slave circuit according to claim 1, wherein the storage unit includes a scan test circuit that receives and stores scan data in a scan mode, the scan mode differing from the sleep mode.

4. The master-slave circuit according to claim 1, further comprising:
a first input data transfer path, provided between the master circuit and the storage unit, which transfers the input data to the storage unit,
wherein the first input data transfer path is coupled to a first switching unit that is switched responsive to the sleep mode setting signal.

5. The master-slave circuit according to claim 4, wherein the first switching unit includes a transfer gate that is controlled based on the sleep mode setting signal.

6. The master-slave circuit according to claim 1, wherein the first control unit includes:
a first delay signal generating unit that generates a first delay signal by delaying the sleep mode setting signal; and
a second switching unit that is coupled between a supply path of the power supply voltage and the master circuit, the second switching unit being controlled based on the first delay signal.

7. The master-slave circuit according to claim 6, wherein the second switching unit includes a metal oxide semiconductor (MOS) transistor that is controlled based on the delay signal.

8. The master-slave circuit according to claim 1, further comprising:
a plurality of master circuits coupled to the first control unit; and
a plurality of slave circuits coupled to the first control unit.

9. The master-slave circuit according to claim 2, further comprising:
a load coupled to the slave circuit,
wherein the slave circuit further includes an interrupting unit that interrupts a transmission of the input data to the load in response to the sleep mode setting signal.

10. The master-slave circuit according to claim 2, further comprising:
a second control unit that steps down the power supply voltage supplied to the slave circuit to a data preservation voltage in response to the sleep mode setting signal, wherein the data preservation voltage is equal to or greater than a voltage that is sufficient to support the preservation of the input data.

11. The master-slave circuit according to claim 10, further comprising:
a plurality of master circuits coupled to the second control unit; and
a plurality of slave circuits coupled to the second control unit.

12. The master-slave circuit according to claims 4, further comprising:
a second input data transfer path that is coupled in parallel with the first input data transfer path and is located between the master circuit and the scan test circuit, the second input data transfer path being capable of transferring the input data to the scan test circuit,
wherein the second input data transfer path is coupled to a third switching unit that is controlled based on a scan mode setting signal for setting the scan mode.

13. The master-slave circuit according to claim 12, further comprising:
a third control unit that interrupts the supply of the power supply voltage to the master circuit and the slave circuit in response to the sleep mode setting signal, after transferring the input data to the scan test circuit.

14. The master-slave circuit according to claim 13, further comprising:
a third input data transfer path, provided between the scan test circuit and the slave circuit, which transfers the input data stored in the scan test circuit to the slave circuit,
wherein the third input data transfer circuit is coupled to a latch unit that latches the input data in response to the sleep mode setting signal.

15. The master-slave circuit according to claim 13, wherein the third control unit includes:
a second delay signal generating unit that generates a second delay signal by delaying the sleep mode setting signal; and
a fourth switching unit that is coupled between the power supply voltage and the master circuit and between the power supply voltage and the slave circuit, and that is controlled based on the second delay signal.

16. A method of controlling a master-slave circuit that includes a master circuit and a slave circuit, the method comprising:
receiving input data in the master circuit in response to a sleep mode signal for setting a sleep mode to store the input data in a storage unit; and
interrupting the supply of a power supply voltage to the master circuit after storing the input data.

17. The method of controlling a master-slave circuit according to claim 16, further comprising:
switching an input data transfer path, which is located between the master circuit and the input data storing unit, in response to the sleep mode setting signal so as to transfer the input data to the storage unit.

18. The method of controlling a master-slave circuit according to claim 17, further comprising:
controlling a gate voltage of a transfer gate in the input data transfer path in response to the sleep mode setting signal.

19. The method of controlling a master-slave circuit according to claim 16, further comprising:
generating a first delay signal by delaying the sleep mode setting signal; and
interrupting the supply of the power supply voltage to a supply path for supplying the power supply voltage in response to the first delay signal.

20. The method of controlling a master-slave circuit according to claim 16, further comprising:
stepping down the power supply voltage supplied to the slave circuit to a data preservation voltage in response to the sleep mode setting signal,
wherein the data preservation voltage is equal to or greater than a voltage that is sufficient to support preservation of the input data.
